(19) United States
(12) Patent Application Publication
(10) Pub. No.: US 2007/0222053 A1
(43) Pub. Date: Sep. 27, 2007

(54) Semiconductor constructions having interconnect structures, methods of forming interconnect structures, and methods of forming semiconductor constructions

(75) Inventors: Zhou Wei, Singapore (SG); Chia Yong Poo, Singapore (SG)

Correspondence Address: WELLS ST. JOHN P.S., 601 W. FIRST AVENUE, SUITE 1300, SPOKANE, WA, 99201, US

(73) Assignee: Micron Technology, Inc.

(21) Appl. No.: 11/436,172

(22) Filed: May 16, 2006

(30) Foreign Application Priority Data
Mar. 27, 2006 (SG) 200602012-7

(51) Int. Cl. H01L 23/02

(52) U.S. Cl. 257/686

(57) ABSTRACT

The invention includes methods of forming semiconductor interconnect structures. A substrate is provided having metal bumps associated with contact pads. A plate having a plurality of cavities containing solder is provided. The metal bumps are inserted into the cavities. The invention includes methods of forming surface-mounting structures. A wafer having a plurality of dies is provided. Each die has contact pads with associated projecting metal bumps. A plate is provided having a pattern of solder-filled cavities corresponding to a layout of the contact pads. The metal bumps are inserted into the cavities and the solder is reflowed to form metal-cored solder bumps. The invention includes constructions such as integrated circuitry chips, wafers and chip package assemblies having a plurality of interconnect structures. The interconnect structures comprise a metal core within an outer solder bump, and are electrically and physically associated with contact pads.

### RELATED PATENT DATA

This application claims priority under 35 U.S.C §119 to Singapore Patent Application 2006-02012-7, which was filed Mar. 27, 2006.

### TECHNICAL FIELD

The present invention pertains to methods of forming interconnect structures on a substrate, methods of forming surface mounting structures on integrated circuitry chips, and includes semiconductor constructions including semiconductor wafers, integrated circuit chips and semiconductor assemblies.

### BACKGROUND OF THE INVENTION

Semiconductor devices, for example, dynamic random access memory (DRAM) devices, are shrinking in the sense that smaller devices are being manufactured which are capable of handling larger volumes of data at faster data transfer rates. As a result, higher numbers of electronic components are present in a given area of integrated circuitry. This increasing density in turn leads to the need for increasingly fine pitched interconnect structures for physically and or electrically connecting the integrated circuitry to external support structures and external circuitry.

After wafer level fabrication of integrated circuitry, chips are typically separated from the wafer and are mounted to packaging or directly onto a printed circuit board (PCB) or other support substrate. The mounting process, commonly referred to as packaging, allows electrical connection of the chip and integration into an electrical system.

Two exemplary conventional techniques utilized for mounting integrated circuitry chips to a support structure are shown in FIGS. 1 and 2. Each of the assemblies 10, 11, shown in FIGS. 1 and 2 includes a semiconductor component 12 (such as, for example, an integrated circuit (IC) chip), and a support substrate 16 to which semiconductor component 12 is mounted. Support substrate 16 can be, for example a package board or printed circuit board.

Integrated circuit chip 12 can comprise various circuit components (not shown) such as, for example, capacitors and transistors. Attachment between chip 12 and board 16 is through a series of electrical interconnect structures. These interconnect structures include contact pads 14 associated with chip 12, contact pads (landing pads) 18 associated with support substrate 16, and intervening structures.

Referring to FIG. 1, chip 12 can be described as having a first surface 25 and an opposing second surface 27. First surface 25 can be referred to as a front surface and second surface 27 can be referred to as a back surface. Similarly, support substrate/board 16 can be described as having a top surface 17 and an opposing bottom surface 19. The relative terms ‘top’, ‘bottom’, ‘front’ and ‘back’ are utilized for descriptive purposes only with an understanding that the relative positioning of such surfaces can differ when assembly 10 is inverted or otherwise repositioned.

The assembly shown in FIG. 1 chip 12 is surface mounted to support substrate/board 16 utilizing solder bumps 20 which physically and electrically joins the chip to the board through the respective contact pads 14 and 18. Assembly 10 depicted in FIG. 1 is an example of under bump metallurgy (UBM) based solder joint flip-chip-on-package structure, where the term ‘flip chip’ refers to positioning of the chip in an inverted position relative to the board such that the front side of the chip facing the top side of the board. An underfill material 22 is present in the shown assembly which can provide mechanical strength and protection of the assembly. Underfill material 22 can be, for example, a non-conductive material. In alternative technologies, underfill 22 may be absent of may utilize alternative types of materials.

Referring to FIG. 2, an alternative interconnect technique is illustrated which utilizes metal bumps 24 such as gold stud bumps to physically and electrically join conductive contact pads 14 associated with chip 12 to conductive contacts such as bond fingers 18 associated with board 16. In the shown exemplary assembly, an anisotropic conductive film 28 is disposed between chip 12 and board 16. Accordingly, the structure assembly 11 shown in FIG. 2 can be referred to as an anisotropic conductive film (ACF) based flip-chip-on-package (FCOP). In the exemplary ACF structure shown, conductive particles 26 are trapped during the packaging process becoming part of the interconnect structure. In alternative constructions, particles 26 may be absent (not shown).

Conventional processes such as chip alignment, chip mounting, and formation of interconnect structures to form flip-chip packages such as those depicted in FIGS. 1 and 2 can be difficult and expensive. Additionally, both the solder bump technology illustrated in FIG. 1, and the ACF technology illustrated in FIG. 2, along with other conventional packaging techniques, can be limited in their ability to achieve fine pitch interconnect structures for use with new generation high density integrated circuitry. Accordingly, it is desirable to develop alternative interconnect structures and methods of interconnecting integrated circuit chips to support substrates.

### BRIEF DESCRIPTION OF THE DRAWINGS

Preferred embodiments of the invention are described below with reference to the following accompanying drawings.

FIG. 1 is a diagrammatic cross-sectional sideview of a prior art UBM-FCOP semiconductor package construction.

FIG. 2 is a diagrammatic cross-sectional sideview of a prior art ACF-FCOP semiconductor package construction.

FIG. 3 is a diagrammatic fragmentary top view of a plate utilized during methods of interconnect structure fabrication in accordance with one aspect of the invention.

FIG. 4 is a diagrammatic fragmentary cross-sectional view of the plate shown in FIG. 3 taken along line 4-4 of FIG. 3.

FIG. 5 is a diagrammatic fragmentary cross-sectional sideview of the plate shown in FIG. 4 at a processing stage subsequent to that shown in FIG. 4.

FIG. 6 is a photomicrograph showing solder paste printed on the surface of a glass plate at a pitch of approximately 125 microns.

FIG. 7 is a diagrammatic fragmentary cross-sectional sideview of aligned chip and plate at a processing step subsequent to that shown in FIG. 5.

FIG. 8 is a diagrammatic cross-sectional sideview of the chip and plate illustrated in FIG. 7 shown at a processing stage subsequent to that shown in FIG. 7.

FIG. 9 is a diagrammatic fragmentary cross-sectional sideview of the chip shown in FIG. 7 subsequent to the processing step of FIG. 8.

FIG. 10 shows a diagrammatic cross-sectional sideview of an exemplary semiconductor assembly incorporating the chip shown in FIG. 9 further processed in accordance with methodology of the invention.

FIG. 11 shows a cross-sectional view photomicrograph of a flip-chip-on-module assembly formed in accordance with methodology of the invention.

FIG. 12 shows a processor system including a semiconductive package formed in accordance with methodologies of the present invention.

### DETAILED DESCRIPTION OF THE PREFERRED EMBODIMENTS

This disclosure of the invention is submitted in furtherance of the constitutional purposes of the U.S. Patent Laws “to promote the progress of science and useful arts” (Article 1, Section 8).

In general the invention includes methods of forming interconnect structures suitable for utilization in semiconductor assemblies such as semiconductor packages and in particular, for mounting integrated circuit chips to substrates such as board substrates. More specifically, methodology of the invention includes formation of a solder bump or ‘ball’ disposed externally around an internal metal bump to form a so called metal-cored solder bump. The methodology can allow low cost, time efficient formation of fine pitch interconnect structures.

Methodologies of the present invention are suitable for utilization in a diverse array of semiconductor assemblies. Exemplary semiconductor packages which can be formed include various flip chip applications where the inverted chip is surface mounted to a substrate which can be, for example, a package board or printed circuit board. It is to be understood that the methodologies described herein can be utilized with other support substrates besides board substrates.

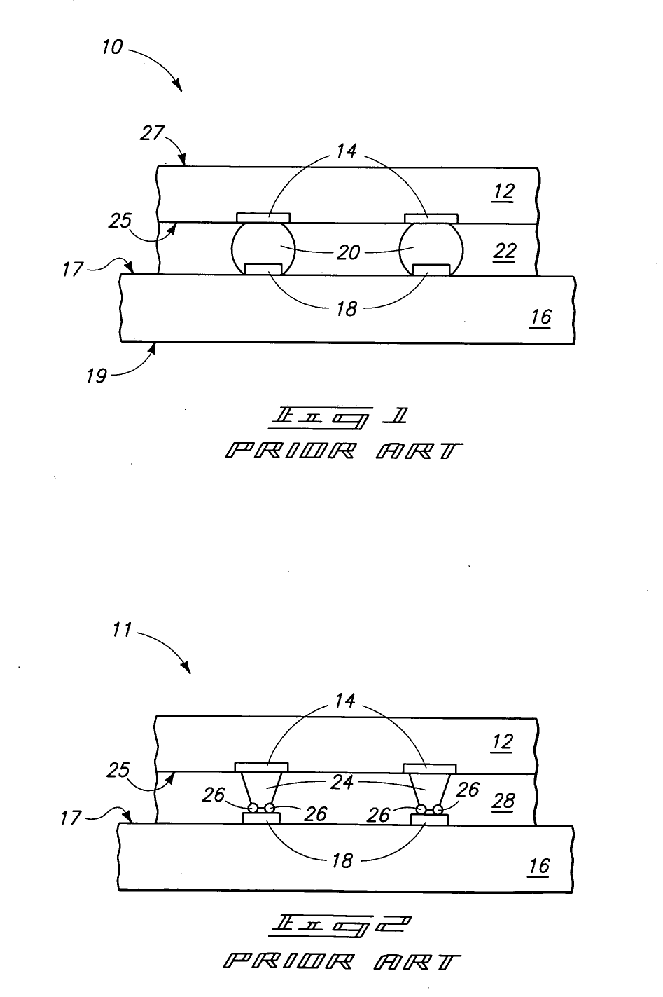

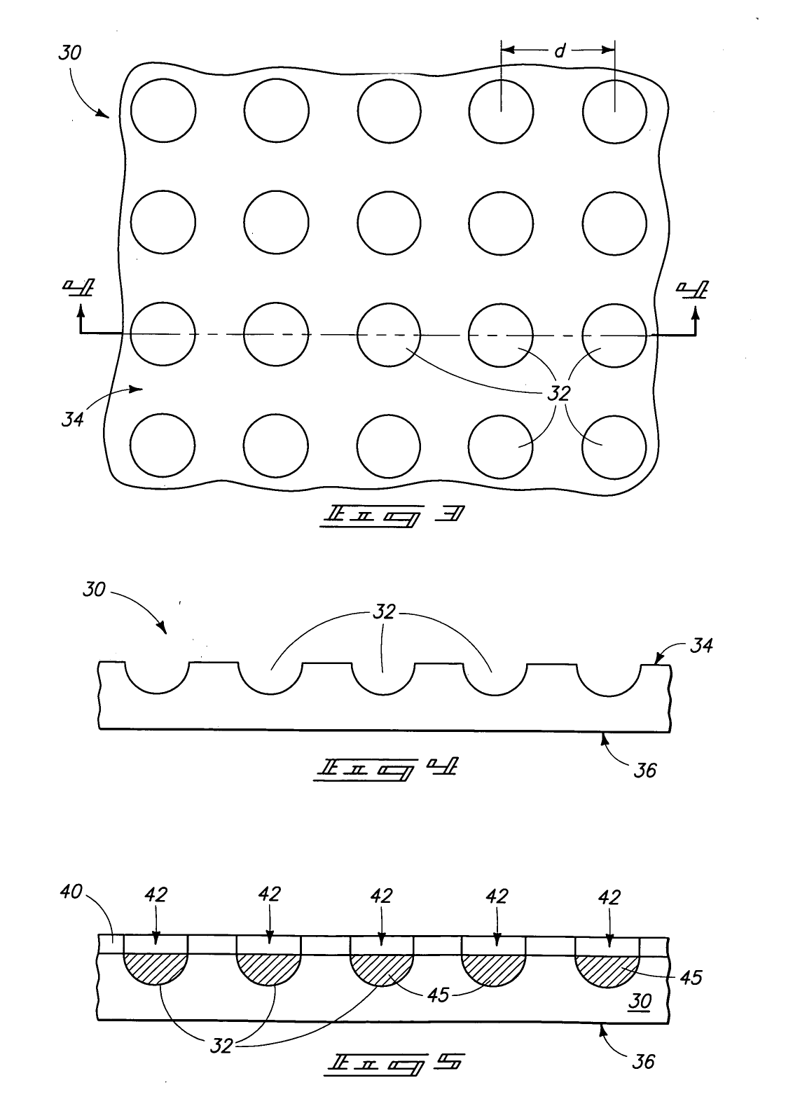

Methodology according to one aspect of the invention is described with reference to FIGS. 3-10. In referring to the embodiments that follow, similar numbering will be utilized as was utilized in describing prior art FIGS. 1-2 where appropriate. Referring initially to FIG. 3, a front surface 34 of a plate 30 is illustrated having a plurality of cavities 32. Cavities 32 are disposed in a pattern with such pattern being designed and constructed to correspond to a pattern of conductive contact pads present on a semiconductive substrate. To aid in interpretation of the claims that follow, the terms “semiconductive substrate” and “semiconductor substrate” are defined to mean any construction comprising semiconductive material, including, but not limited to, bulk semiconductive materials such as a semiconductive wafer (either alone or in assemblies comprising other materials thereon), and semiconductive material layers (either alone or in assemblies comprising other materials). The term “substrate” refers to any supporting structure, including, but not limited to, the semiconductive substrates described above. When utilized for the present description, the term “semiconductive substrate” can typically refer to a semiconductive wafer, wafer fragment or integrated circuit chip. The term ‘support substrate’ is utilized to refer to a substrate such as, for example, a board substrate to which the semiconductor substrate is mounted or is to be mounted.

The pattern of cavities 32 shown in FIG. 3 is but an exemplary pattern to illustrate aspects of the invention. The pattern ‘pitch’ of the exemplary pattern shown in FIG. 3 is represented by distance “d” which corresponds to the center-to-center cavity distance.

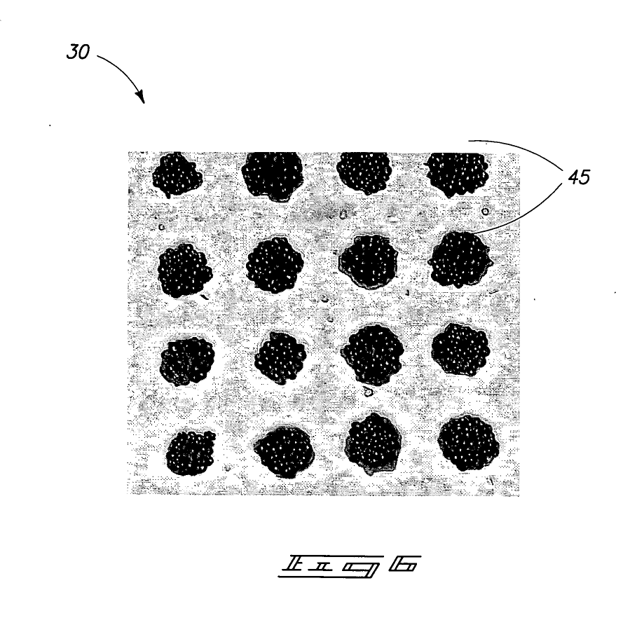

Referring to FIG. 4 such shows a cross-sectional sideview of plate 30 shown in FIG. 3. As illustrated in FIG. 4, plate 30 has an upper (front) surface 34 comprising the pattern of cavities 32, and an opposing bottom (back) surface 36. The volume of cavities 32 is not limited to a particular volume and can preferably have a volume sufficient to contain a desired amount of solder material as will become clear in the following discussion. Plate 30 can be formed of a suitable non solder-wettable material such as, for example, glass, silicon materials, ceramics or combinations thereof. Cavities 32 can be formed by, for example, etching or other appropriate method based upon the plate material, to produce the cavity pattern corresponding to a contact pad layout (discussed below).

Referring to FIG. 5, a solder material 45 such as, for example, solder paste is provided to at least partially fill cavities 32. A stencil 40 can optionally be utilized having openings 42 which extend through the stencil material where openings 42 are disposed in a pattern which corresponds to the pattern of underlying cavities 32.

Solder material 45 can be introduced into cavities 32 by, for example, printing solder paste directly into the cavities of the plate. Such direct printing can occur in the presence or absence of optional stencil 40 since the cavity pattern can itself serve as a stencil. Where the solder material is a solder paste, the paste is not limited to a particular type. Where the pattern of contact pads and the corresponding pattern of plate cavities are fine pitched, it can be preferable to use a type 6 or type 7 solder paste. Due to the increased cost associated with smaller particle solder paste, it can be desirable to select a solder paste based upon the ultimate pitch to be achieved. For example, type 6 solder can be utilized to achieve a pitch as fine as 125 microns or less. Utilizing type 7 solder, a pitch as fine as 90 microns or less can be achieved.

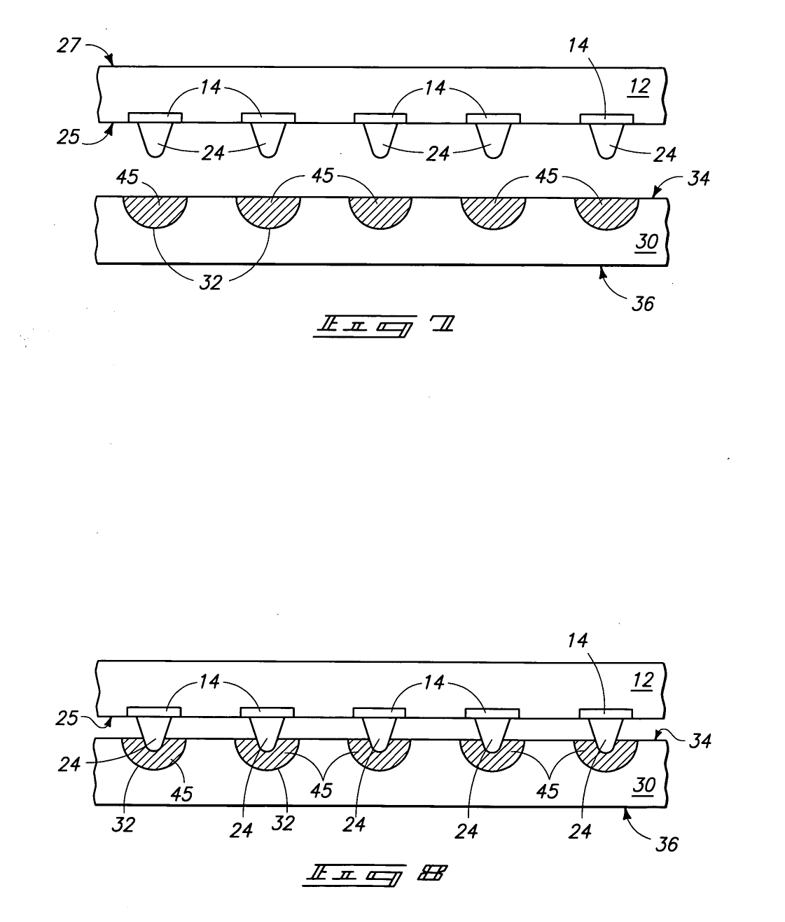

Referring to FIG. 6, such shows the results of direct printing of type 7 solder paste (particle size 5-15 μm) on an upper (flat) surface 34 of a plate 30. The print pitch of plate 30 shown in FIG. 6 is 125 microns. As shown, the printing produced a well defined solder pattern with no solder bridging or missing pattern elements.

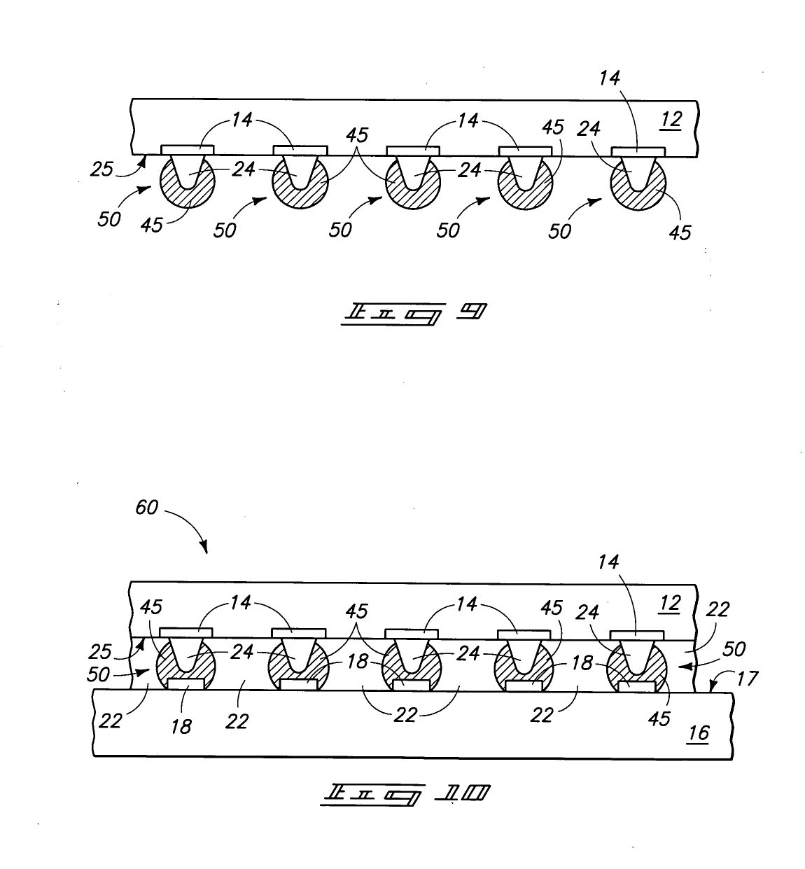

Referring to FIG. 7, a fragment of a semiconductor substrate 12 is illustrated in conjunction with a plate 30 having solder-filled cavities. As discussed above, semiconductor substrate 12 can be, for example, a wafer, a wafer fragment or an individual integrated circuit chip. To minimize cost and maximize efficiency, it can be preferable to perform interconnect structure formation in accordance with the invention at the wafer level. Accordingly semiconductor substrate 12 can preferably be an entire wafer. Where substrate 12 is a wafer or wafer fragment, such can comprise a plurality of defined dies which can be separated subsequent to the processing stage depicted in FIGS. 7-9. It is to be understood however that the methodology of the invention can be utilized to form interconnect structures on less than an entirety of a wafer or upon individual integrated circuit chips. With this in mind, the size of plate 30 can vary depending upon the particular substrate 12 to be processed. Further, the shape of plate 30 and the size of plate 30 relative to substrate 12 are not limited to the shape and size of substrate 12. Accordingly, plate 12 can be circular or non-circular and can have an area of surface 36 which equals or exceeds the area over which substrate surface 25 is to be ‘bumped’.

As discussed above, semiconductor substrate 12 can comprise various electrical components not specifically illustrated in the figures. Substrate 12 can comprise a pattern of conductive contact pads 14 disposed along or over a first surface 25, where first surface 25 is a surface that will interface a support substrate (package board, PCB, etc.). The pattern or layout of contact pads 14 is not limited to a particular pattern or pitch.

Semiconductor substrate 12 can further comprise a plurality of metal bumps 24 where each of the metal bumps projects from and is physically and electrically associated with one of conductive contact pads 14. Metal bumps 24 can be, for example, metal stud bumps and can be formed utilizing techniques known to those skilled in the art. Metal bumps 24 can comprise an appropriate conductive material including, but not limited to, conductive materials comprising gold, copper, aluminum, solder materials, or combinations thereof. In particular instances, the metal bumps can consist essentially of, or can consist of one or more of these materials.

The plate/semiconductor substrate combination illustrated in FIG. 7 is shown in alignment such that each of metal bumps 24 is horizontally aligned over a cavity 32 comprised by plate 30. Alignment of the substrate and plate 30 can be performed utilizing conventional alignment techniques. Such alignment is further assisted by the insertability of metal bumps 24 into cavities 32.

Referring to FIG. 8, such illustrates the plate/substrate combination in an inserted position where metal bumps 24 are inserted into solder material 45 within cavities 32. The depth of insertion of the metal bumps within cavities 32 is illustrated for ease of description. It is to be under stood that plate 30 and substrate 12 can be brought into closer proximity relative to that depicted in FIG. 8 such that metal bumps 24 are more fully or completely inserted within cavities 32.

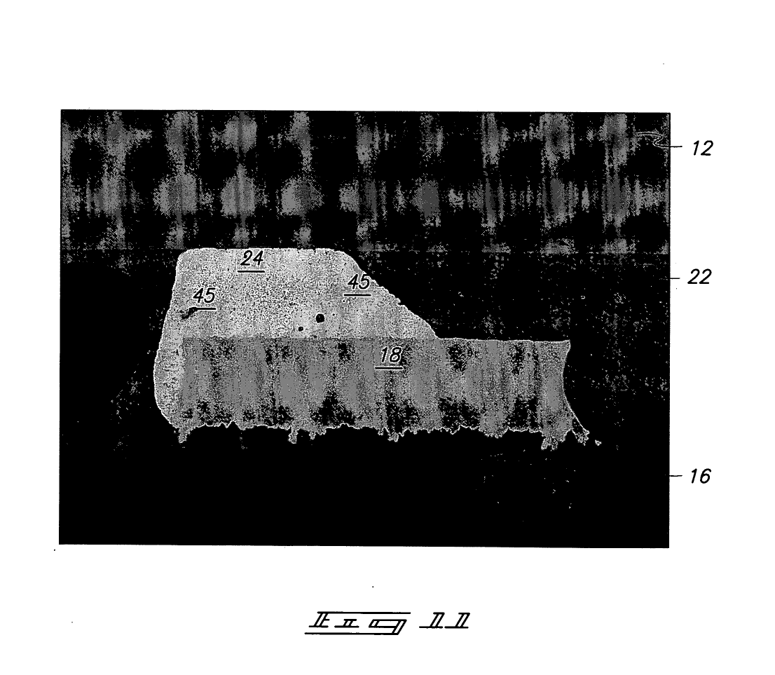

Referring next to FIG. 9, further processing can comprise reflow of solder material 45 resulting in solder bump formation to form solder bumps or ‘balls’ externally around metal bumps 24. Solder bumps 50 are shown in FIG. 9 after solder reflow and removal of plate 30. Solder bumps 50 can be referred to as metal-cored solder bumps with such metal-cored solder bumps being an interconnect structure having an internal metal bump 24, at least a portion of which is surrounded by an external solder material 45.

The solder reflow processing can be performed utilizing solder reflow techniques and conditions known to those skilled in the art, as appropriate for the particular type of solder material utilized. After the solder reflow and removal of plate 30 as depicted in FIG. 9, solder paste has been transferred from the plate to the wafer to complete the solder bumping process. Where the semiconductor substrate 12 is an entire wafer or wafer fragment, such can be further processed to separate the wafer into individual dies (integrated circuitry chips) having interconnect structures for interconnection of the integrated circuitry to external components.

Referring to FIG. 10, an exemplary assembly 60 is shown having semiconductor substrate 12 surface-mounted to a support substrate 16. Support substrate 16 can be, for example, a package board, a printed circuit board, an additional integrated circuit substrate, or a silicon wafer or fragment having circuitry. Metal-cored solder balls 50 are utilized to physically and electrically connect the semiconductor substrate to the support substrate. As illustrated, support substrate 16 has a plurality of contact (landing) pads such as bond fingers positioned to align with conductive contacts 14. Assembly 60 can be formed by, for example, aligning metal-cored solder bumps 50 on inverted substrate 12 with contacts 18 of the support substrate, contacting the solder 45 of the metal-cored solder bumps with contact pads 18 and reflowing solder material 45 to form a physical and electrical interconnect structure between the contact pads 14 associated with the semiconductor substrate and the aligned contact pads 18 associated with the support substrate 16.

As illustrated in FIG. 10, an underfill material 22 can be provided between interfacing surfaces (first surface 25 of substrate 12 and top surface 17 of support substrate 16). Such underfill material can provide protection, support, and mechanical strength to the assembly. Underfill material 22 can comprise, for example, a non-conductive material such as epoxy resin, and can be provided utilizing underfill techniques known to those skilled in the art.

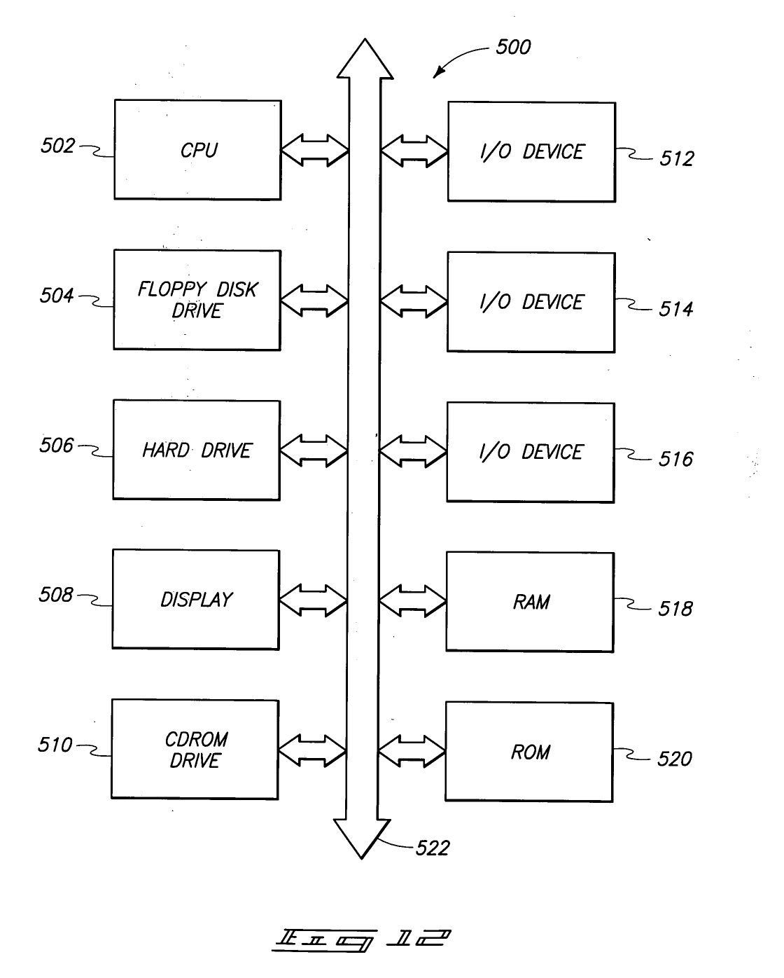

Referring to FIG. 11 such shows a cross-section of an assembly formed in accordance with methodology of the invention. The intermetallic structure shown comprises a gold stud bump core surrounded by solder 45 bonded to a copper bond finger 18 associated with support substrate 16 (PCB). The cross-section shows that methodology of the invention produces a robust intermetallic joint. Study of reliability of the formed metal-cored solder bump intermetallic joint indicates increased reliability relative to conventional flip-chip technologies such as, for example, conventional C4, ACF, and non-conductive paste (NCP) based flip-chip technologies.

Methodology of the invention advantageously allows an extremely low cost wafer solder bumping without wafer level rerouting, plating or dispensing of conductive material. Additionally, since the metal bump on wafer is utilized as under bump metallization, the resulting intermetallic structure can be utilized without additional under bump metallization processing.

The methodology of the invention is additionally advantageous due to ease of process relative to conventional techniques. The solder paste printing process of the invention on a flat fixture (plate) avoids more complex processing such as printing on PCB substrate bond fingers or directly onto wafer surfaces, where bridging could easily occur due to uneven surfaces. Methodology of the invention allows high efficiency wafer level solder bumping and can achieve fine pitch bumping. Current solder paste materials can be utilized in methodology of the invention to produce fine pitch bumping of 90 microns. Further pitch reduction is expected utilizing methodology of the invention in conjunction with improved or yet to be developed solder materials.

In addition to improved solder joint reliability, the interconnect methodology of the invention allows a larger stand up height in flip-chip connection technology.

FIG. 12 illustrates an exemplary processor system that may include semiconductor components produced using various packaging methodology of the present invention. Specifically, a processor system 500 is illustrated which can be, for example, a computer system. The processor system generally comprises a central processing unit (CPU) 502, for example, a microprocessor that communicates with one or more input/output (I/O) devices 512, 514, and 516 over a system bus 522. System 500 also includes random access memory (RAM) 518, a read-only memory (ROM) 520 and may also include peripheral devices such as a floppy disk drive 504, a hard drive 506, a display 508 and a compact disk (CD) ROM drive 510 which also communicate with the processor 502 over the bus 522. Any or all of the elements of the processor system 500, for example, processor 502, RAM 518, ROM 520 or controller or other IC chips contained within the components shown in FIG. 12 may include semiconductor packages formed using methodology described herein. It should be noted that FIG. 12 is representative of many different types of architectures of a processor system 500 which may employ the invention. It may also be desirable to integrate the CPU 502 and the RAM 518 on a single chip.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

The invention claimed is:

1. A method of forming interconnect structures on a substrate, comprising:
providing a substrate having a plurality of metal bumps associated with contact pads;
providing a plate having a plurality of cavities;
providing a solder material within the cavities; and
inserting the metal bumps into the cavities.

2. The method of claim 1 wherein the metal bumps are Au-comprising stud bumps.

3. The method of claim 1 wherein the contact pads are comprised by a pattern of contact pads and wherein the plurality of cavities forms a pattern of cavities which mirrors the pattern of contact pads.

4. The method of claim 1 wherein the substrate is a semiconductive wafer.

5. The method of claim 4 wherein the contact pads are disposed on a top surface of the semiconductive plate has a top surface having a top surface area and wherein the cavities are disposed on a front surface of the plate, the from surface of the plate having a front surface area which equals or exceeds the top surface area.

6. The method of claim 1 further comprising:
after the inserting, reflowing the solder material around the metal bumps to form solder bumps having metal cores; and
removing the plate.

7. A method of forming surface mounting structures on integrated circuit chips, comprising:
providing a semiconductive wafer having a plurality of defined dies comprising integrated circuitry, each die having a plurality of contact pads with an associated projecting metal bump;
providing a plate comprising a pattern of cavities across a front surface, the pattern corresponding to a layout of the contact pads across at least a portion of the semiconductive wafer;
at least partially filling each of the cavities with a solder material;
aligning the contact pads with the pattern of cavities;
inserting the projecting metal bumps into the cavities;
reflowing the solder material to form metal-cored solder bumps comprising the reflowed solder material around the metal bumps; and
removing the plate.

8. The method of claim 7 further comprising separating the dies to produce individual integrated circuitry chips.

9. The method of claim 7 wherein the solder comprises at least one of a type 6 and type 7 solder.

10. The method of claim 7 wherein the pattern of cavities has a center-to-center pitch of less than or equal to 90 μm.

11. The method of claim 7 wherein the projecting metal bump comprises gold.

12. A semiconductive wafer comprising:
a plurality of dies, each of the dies comprising a plurality of conductive contact pads; and
a plurality of interconnect structures each comprising a metal core within an outer solder bump, each interconnect structure being individually electrically and physically associated with one of the conductive contact pads.

13. The semiconductive wafer of claim 12 wherein the metal core comprises gold.

14. The semiconductive wafer of claim 12 wherein the metal core comprises a metal stud bump.

15. The semiconductive wafer of claim 12 wherein the plurality of conductive pads form a pattern having a pitch of 125 microns or less.

16. An integrated circuit chip comprising a plurality of interconnect structure structures having a metal core within a solder bump.

17. The integrated circuit chip of claim 16 wherein the chip comprises a plurality of conductive contact pads and wherein each interconnect structure is individually electrically and physically associated with one of the conductive contact pads.

18. The integrated circuit chip of claim 17 wherein the metal core is comprised by a metal bump which projects outward relative a surface of the associated contact pad.

19. The integrated circuit chip of claim 16 wherein the chip is bonded to a support substrate to form a semiconductor assembly.

20. The integrated circuit chip of claim 19 wherein the support substrate is selected from the group consisting of a printed circuit board, a package board, an integrated circuit, and a silicon wafer having circuitry.

21. An semiconductor assembly comprising:
a support substrate; and
an integrated circuitry chip mounted to the support substrate by a plurality of interconnect structures comprising metal-cored solder bumps.

22. The semiconductor assembly of claim 21 wherein the support substrate is selected from the group consisting of a printed circuit board, a package board, an integrated circuit, and a silicon wafer having circuitry.

23. The semiconductor assembly of claim 21 wherein the metal core of the metal-cored solder bumps comprise gold.

24. The semiconductor assembly of claim 21 wherein the metal core of the metal-cored solder bumps is a metal bump which projects outward from a contact pad comprised by the integrated circuit chip.

25. The semiconductor assembly of claim 21 wherein the metal-cored solder bumps are physically and electrically connected to bond fingers present on the support substrate.

26. The semiconductor assembly of claim 25 wherein the bond finger comprises copper.

27. A processor system comprising:
an integrated circuit chip;
a support substrate; and
a plurality of interconnect structures connecting the integrated circuit chip to the support substrate, each of the interconnect structures comprising a metal-cored solder bump comprising an internal metal bump and an external solder material, the metal bump projecting outward from a contact pad comprised by the integrated circuit chip.
